(19) United States
(12) Patent Application Publication
(10) Pub. No.: US 2009/0220822 A1
(43) Pub. Date: Sep. 3, 2009

(54) FERROELECTRIC RECORDING MEDIUM AND METHOD OF MANUFACTURING THE SAME

(75) Inventors: Simon BUEHLMANN, Yongin-si (KR); Yong-kwan KIM, Yongin-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD., Suwon-si (KR)

(21) Appl. No.: 12/239,163

(22) Filed: Sep. 26, 2008

(30) Foreign Application Priority Data
Feb. 29, 2008 (KR) 10-2008-0019303

(51) Int. Cl. G11B 5/706; H01L 21/00

(52) U.S. Cl. 428/846; 438/3; 257/E43.006

(57) ABSTRACT

Provided are a ferroelectric recording medium and a method of manufacturing a ferroelectric recording medium. The method includes forming an electrode layer of a conductive material on a substrate, forming an intermediate layer of a dielectric material on the electrode layer, forming a source material layer on the intermediate layer, and forming a ferroelectric layer from the source material layer by performing an annealing process.

### CROSS-REFERENCE TO RELATED PATENT APPLICATION

This application claims priority from Korean Patent Application No. 10-2008-0019303, filed on Feb. 29, 2008 in the Korean Intellectual Property Office, the disclosure of which is incorporated herein in its entirety by reference.

### BACKGROUND OF THE INVENTION

1. Field of the Invention

The present invention relates to a recording medium and a method of manufacturing the same, and more particularly, to a ferroelectric recording medium onto which high density data can be recorded and a method of manufacturing the same.

2. Description of the Related Art

With the rapid development of data storage apparatuses such as conventional hard discs and optical discs, information storage apparatuses having a recording density of 1 Gbit/inch² or more have been developed, and the rapid development of digital techniques demand for a further increase in the capacity of information storage apparatuses. However, the recording density of conventional information storage apparatuses is limited due to super paramagnetic limitations of hard discs or diffraction limitations of a laser of an optical disc.

Recently, studies have been conducted with regard to a ferroelectric recording medium on which data is recorded by using an electric field instead of a magnetic field. In an electric field recording method, after forming electric domains polarized in a first direction and a second direction which is opposite to the first direction are formed on a surface of a ferroelectric recording medium using an electric field, the electric domains polarized in the first and second directions respectively correspond to data ‘0’ and ‘1’. A reproduction process is performed using an electric field sensor in which resistance changes according to polarization directions of the electric domains. In an electric field recording and reproducing method, a high recording density of 1 Tb/in² or more can be obtained.

The electric field recording and reproducing method can use a driving mechanism of a hard disc drive used in the conventional magnetic recording method and can also greatly increase the recording density. Thus, there is a need to develop a ferroelectric recording medium and a method of manufacturing the same.

### SUMMARY OF THE INVENTION

The present invention provides a ferroelectric recording medium that allows high density recording and reproducing data, and a method of manufacturing the same.

According to an aspect of the present invention, there is provided a method of manufacturing a ferroelectric recording medium, the method comprising: forming an electrode layer of a conductive material on a substrate; forming an intermediate layer of a dielectric material on the electrode layer; forming a source material layer on the intermediate layer; and forming a ferroelectric layer from the source material layer by performing an annealing process.

The method may further comprise forming a capping layer on the source material layer to prevent volatilization of the source material layer.

The ferroelectric layer may be formed of a material selected from the group consisting of PbTiO₃, Pb(Zr, Ti)O₃, LiNbO₂, LiTaO₃, BiFeO₃, and PVDF.

The intermediate layer may be formed of a material selected from the group consisting of ZrO₂, TiO₂, MgO₂, SrTiO₃, Al₂O₃, HfO₂, Nb oxide, SiO₂, and ZnO₂.

The source material layer may be the same material layer as the ferroelectric layer.

The source material layer may comprise a plurality of material layers that form the ferroelectric layer by a reaction occurring between the material layers, and the material layers may comprise first and second material layers that are alternately stacked at least two times.

The annealing process for forming the ferroelectric layer may be performed at a temperature of 500° C. or below.

The forming of the electrode layer may comprise forming the conductive material layer on the substrate by depositing a conductive material and annealing the substrate on which the conductive material layer is formed at a temperature of 500° C. or below.

Prior to annealing the substrate on which the conductive material layer is formed, the forming of the electrode layer may further comprise forming a deformation prevention layer on a surface of the substrate opposite to the surface on which the conductive material layer is formed to prevent the substrate from being deformed during the annealing process.

The forming of the intermediate layer may comprise depositing a seed material, which is a dielectric material, on the substrate and forming the dielectric material layer by oxidizing the seed material by performing an annealing process in a gas atmosphere that contains oxygen.

According to another aspect of the present invention, there is provided a method of manufacturing a ferroelectric recording medium, the method comprising: forming an electrode layer on a substrate by depositing and annealing a conductive material layer on the substrate; forming an intermediate layer on the electrode layer, in which the intermediate layer is formed of one material selected from the group consisting of ZrO₂, TiO₂, MgO₂, SrTiO₃, Al₂O₃, HfO₂, Nb oxide, SiO₂, and ZnO₂; depositing at least one source material layer on the intermediate layer to form a ferroelectric layer formed of one material selected from the group consisting of PbTiO₃, Pb(Zr, Ti)O₃, LiNbO₂, LiTaO₃, BiFeO₃, and PVDF; and forming the ferroelectric layer from the source material layer by performing an annealing process at a temperature of 500° C. or below in an Ar—O₂ mixture gas atmosphere which contains 5% oxygen.

According to an aspect of the present invention, there is provided a ferroelectric recording medium including a substrate; an electrode layer disposed on the substrate; a ferroelectric layer; and an intermediate layer between the electrode layer and the ferroelectric layer, wherein the intermediate layer induces the crystal orientation direction of the ferroelectric layer in a predetermined dominant orientation direction.

The ferroelectric recording medium may further comprise a deformation prevention layer disposed on a surface of the substrate opposite to the surface on which the electrode layer is disposed in order to prevent the substrate from being deformed.

The ferroelectric recording medium may further comprise: an adhesive layer disposed between the substrate and the electrode layer; and a deformation prevention layer disposed on a surface of the substrate opposite to the surface on which the electrode layer is formed in order to prevent the substrate from being deformed, wherein the deformation prevention layer may have a multi-layer structure formed of the same material used to form the electrode layer and the adhesive layer.

The ferroelectric layer may be formed of one material selected from the group consisting of PbTiO₃, Pb(Zr, Ti)O₃, LiNbO₂, LiTaO₃, BiFeO₃, and PVDF.

The intermediate layer may be formed of one material selected from the group consisting of ZrO₂, TiO₂, MgO₂, SrTiO₃, Al₂O₃, HfO₂, Nb oxide, SiO₂, and ZnO₂.

### BRIEF DESCRIPTION OF THE DRAWINGS

The above and other aspects of the present invention will become more apparent by describing in detail exemplary embodiments thereof with reference to the attached drawings in which:

FIGS. 1A through 1C are cross-sectional views for explaining a method of forming an electrode layer according to an exemplary embodiment of the present invention;

FIG. 1D is a cross-sectional view for explaining a method of forming an intermediate layer according to an exemplary embodiment of the present invention;

FIGS. 1E through 1G are cross-sectional views for explaining a method of forming a ferroelectric layer according to an exemplary embodiment of the present invention;

FIG. 1H is a cross-sectional view of a ferroelectric recording medium manufactured by using the processes described with reference to FIGS. 1A through 1G according to an exemplary embodiment of the present invention;

FIG. 2A is a graph showing X-ray scan data with respect to a sample;

FIG. 2B is a graph showing synchrotron scan data with respect to the sample;

FIG. 2C is a magnified portion of A of FIG. 2B;

FIG. 2D is a graph showing X-ray scan data of a thin film of the sample;

FIG. 2E is a schematic drawing for explaining a method of testing a ferroelectric characteristic of the sample; and

FIG. 3 is a perspective view of an electric field recording and reproducing apparatus having a driving mechanism of a hard disc drive.

### DETAILED DESCRIPTION OF EXEMPLARY EMBODIMENTS OF THE INVENTION

The present invention will now be described more fully with reference to the accompanying drawings, in which exemplary embodiments of the invention are shown. The invention may, however, be embodied in many different forms and should not be construed as being limited to the exemplary embodiments set forth herein; rather, these exemplary embodiments are provided so that this disclosure will be thorough and complete, and will fully convey the concept of the invention to those of ordinary skill in the art. In the drawings, the thicknesses of layers and regions are exaggerated for clarity. Like reference numerals in the drawings denote like elements, and thus their description will be omitted.

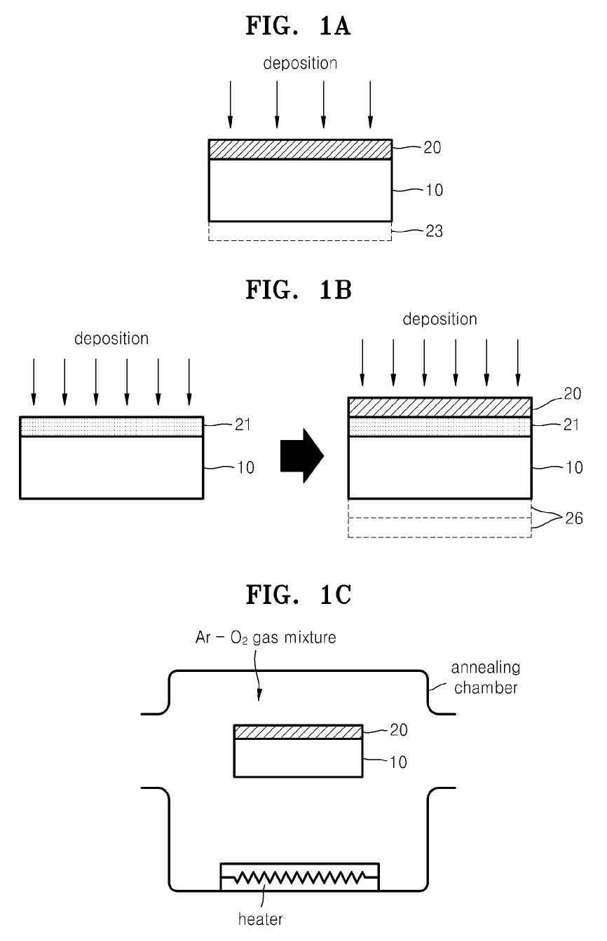

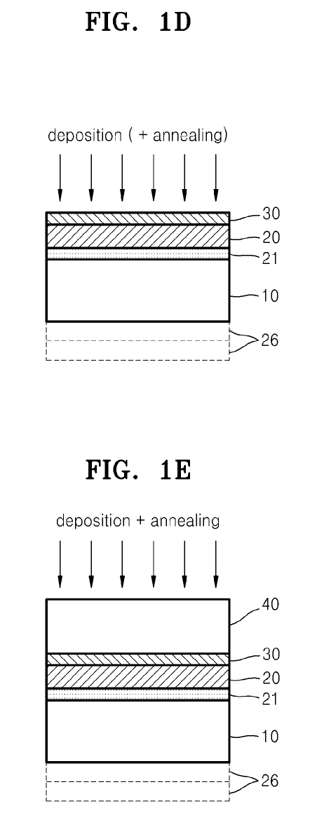

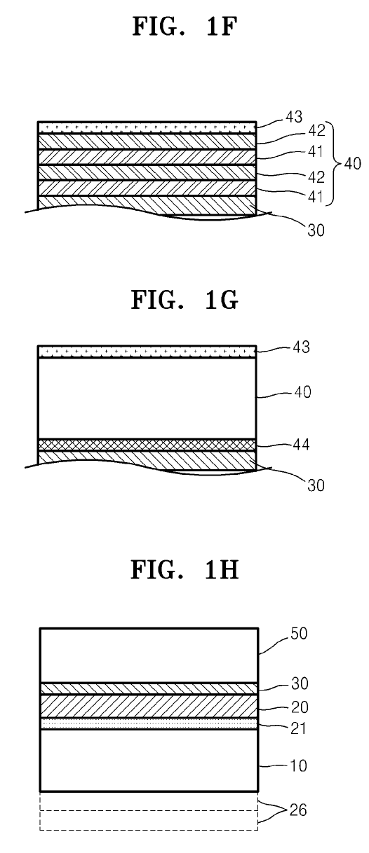

FIGS. 1A through 1C are cross-sectional views for explaining a method of forming an electrode layer 20 according to an exemplary embodiment of the present invention. Referring to FIG. 1A, a conductive material such as Pt, Ir, Ru, Al, Au, RuO₂, SrRuO₃, or IrO₃ is deposited on a substrate. The deposition process may be performed by sputtering, thermal evaporation, chemical vapor deposition (CVD), metal organic chemical vapor deposition (MOCVD), atomic layer deposition (ALD), or pulsed laser deposition (PLD). A thickness of the electrode layer 20 may be 0.5 to 100 nm. The substrate 10 may be various types of substrates, for example, a glass substrate, a silicon substrate, or a polymer substrate.

Referring to FIG. 1B, the process of forming the electrode layer 20 may include a process of depositing an adhesion layer 21 on the substrate 10 and a process of forming the electrode layer 20 by depositing a conductive material on the adhesion layer 21. The adhesion layer 21 may be formed by depositing, for example, Ti, Zr, TiO₂, ZrO₂, Hf, HfO₂ to a thickness of 0.5 to 100 nm on the substrate 10 by using a sputtering method, a thermal evaporation method, a chemical vapor deposition (CVD) method, a metal organic chemical vapor deposition (MOCVD) method, an atomic layer deposition (ALD) method, or a pulsed laser deposition (PLD) method.

Referring to FIG. 1C, the forming of the electrode layer 20 may include an annealing process of the substrate 10 on which the conductive material is deposited by the process described with reference to FIG. 1A or the substrate 10 on which the conductive material and the adhesion layer 21 are deposited by the processes described with reference to FIGS. 1A and 1B. The annealing process may be performed at a temperature in a range from room temperature to 500° C. under an atmosphere of a gas mixture of Ar—O₂. For example, the annealing process may include a step of annealing at a temperature of 400° C. for 2 minutes. The annealing facilitates the formation of crystalline of the electrode layer 20. As a result of annealing, the electrode layer 20 has a very smooth surface. Also, stress that is applied to the substrate 10 during the deposition process may be mitigated due to the annealing.

Prior to performing the annealing process, the process of forming the electrode layer 20 may further include a process of forming a deformation prevention layer 23 on a surface of the substrate 10 opposite to the surface on which the electrode layer 20 is formed as indicated by a dotted line in FIG. 1A. The deformation prevention layer 23 prevents the substrate 10 from bending during the annealing process described above, and thus, increases electrical contact between the electrode layer 20 and the substrate 10. The deformation prevention layer 23 may be formed of the same material used to form the electrode layer 20. As depicted in FIG. 1B, if the electrode layer 20 is formed on the adhesion layer 21, a deformation prevention layer 26 may be a multi-layer structure in which the deformation prevention layer 26 is formed of the same materials used to form the adhesion layer 21 and the electrode layer 20. The deformation prevention layer 23 may be formed on the substrate 10 by depositing the same material used to form the electrode layer 20 by using a sputtering method, a thermal evaporation method, a chemical vapor deposition (CVD) method, a metal organic chemical vapor deposition (MOCVD) method, or an atomic layer deposition (ALD) method. Also, the deformation prevention layer 26 may be formed by sequentially depositing the same materials used to form the adhesion layer 21 and the electrode layer 20 by using a sputtering method, a thermal evaporation method, a chemical vapor deposition (CVD) method, a metal organic chemical vapor deposition (MOCVD) method, an atomic layer deposition (ALD) method, or a pulsed laser deposition (PLD) method.

FIG. 1D is a cross-sectional view for explaining a method of forming an intermediate layer 30 according to an exemplary embodiment of the present invention. Referring to FIG. 1D, the process of forming the intermediate layer 30 includes a process of forming a dielectric material layer formed of, for example, ZrO₂, TiO₂, MgO₂, SrTiO₃, Al₂O₃, HfO₂, Nb oxide, SiO₂, or ZnO₂ on the electrode layer 20. The intermediate layer 30 may be formed by oxidizing a seed material by using annealing under a gas atmosphere containing oxygen after depositing the seed material, for example, Zr, Ti, Mg, Sr, Al, Hf, Nb, Si, or Zn on the electrode layer 20 by using a sputtering method, a thermal evaporation method, a chemical vapor deposition (CVD) method, a metal organic chemical vapor deposition (MOCVD) method, an atomic layer deposition (ALD) method, or a pulsed laser deposition (PLD) method. The annealing may be performed at a temperature of 500° C. or below. For example, the annealing process may include a step of annealing at a temperature of 400° C. for 1 minute. The intermediate layer 30 may also be formed by depositing a dielectric material, for example, ZrO₂, TiO₂, MgO₂, SrTiO₃, Al₂O₃, HfO₂, Nb oxide, SiO₂, or ZnO₂ directly on the electrode layer 20 by using a sputtering method, a thermal evaporation method, a chemical vapor deposition (CVD) method, a metal organic chemical vapor deposition (MOCVD) method, an atomic layer deposition (ALD) method, or a pulsed laser deposition (PLD) method. Also, the intermediate layer 30 may be formed by depositing a seed material, for example, Zr, Ti, Mg, Sr, Al, Hf, Nb, Si, or Zn on the electrode layer 20 at the same time as oxidizing the material by using a reactive deposition process. The annealing process described above may be performed after performing the direct deposition or the reactive deposition. The intermediate layer 30 may be formed to a thickness of 0.5 to 10 nm, and preferably, to a thickness of 1 to 4 nm. The material used to form the intermediate layer 30 has a very smooth surface. In a subsequent process for forming a ferroelectric layer, the intermediate layer 30 maintains high crystallinity in a crystallization process of the ferroelectric layer by inducing the ferroelectric layer to have a predetermined dominant orientation direction. Also, the intermediate layer 30 makes the surface of the ferroelectric layer smooth.

Next, a process of forming the ferroelectric layer is performed. FIGS. 1E through 1G are cross-sectional views for explaining a method of forming a ferroelectric layer according to an exemplary embodiment of the present invention. Referring to FIG. 1E, the process of forming the ferroelectric layer includes a process of depositing a source material layer 40 on the intermediate layer 30 and a process of annealing the source material layer 40 to form the ferroelectric layer. The ferroelectric layer may be a material layer such as PbTiO₃, Pb(Zr, Ti)O₃, LiNbO₂, LiTaO₃, BiFeO₃, or PVDF.

Referring to FIG. 1F, the source material layer 40 may be formed by depositing a plurality of material layers 41 and 42 that form a material layer of PbTiO₃, Pb(Zr, Ti)O₃, LiNbO₂, LiTaO₃, BiFeO₃, or PVDF by reacting each other, on the intermediate layer 30 by using, for example, a sputtering method, a thermal evaporation method, a chemical vapor deposition (CVD) method, a metal organic chemical vapor deposition (MOCVD) method, an atomic layer deposition (ALD) method, or a pulsed laser deposition (PLD) method. The material layers 41 and 42 may be alternately deposited at least two times. The material layers 41 and 42 are formed in an appropriate ratio in consideration of a stoichiometric composition and required ferroelectric characteristics of the ferroelectric layer. A capping layer 43 may further be formed on the material layers 41 and 42 in order to prevent or compensate for the source material loss due to volatilization when the material layers 41 and 42 react with each other in an annealing process which will be described later. The capping layer 43 may be one material layer of the material layers 41 and 42.

Referring to FIG. 1G, the source material layer 40 may be formed by depositing a material, for example, PbTiO₃, Pb(Zr, Ti)O₃, LiNbO₂, LiTaO₃, BiFeO₃, or PVDF on the intermediate layer 30 by using a sputtering method, a thermal evaporation method, a chemical vapor deposition (CVD) method, a metal organic chemical vapor deposition (MOCVD) method, an atomic layer deposition (ALD) method, or a pulsed laser deposition (PLD) method. At this point also, a capping layer 43 may further be formed on the source material layer 40 in order to prevent or compensate for source material loss due to volatilization of the source material layer 40 in an annealing process which will be described later, and the capping layer 43 may be one material layer of the material layers 41 and 42 described above. Also, a starting layer 44 may further be formed between the intermediate layer 30 and the source material layer 40. The starting layer 44 may be one material layer of the material layers 41 and 42.

The annealing process may be performed at a temperature in a range from room temperature to 500° C. For example, the annealing process may include a step of annealing at a temperature 400 to 500° C. for 4 minutes. By performing the annealing process, the material layers 41 and 42 react with each other to form a ferroelectric layer on the intermediate layer 30, and the ferroelectric layer crystallizes in a predetermined orientation direction. If a ferroelectric material is directly used as a source material, the source material crystallizes in a predetermined orientation direction due to the annealing.

As a result of performing the above processes, a ferroelectric recording medium is manufactured as depicted in FIG. 1H. Conventional thin film manufacturing processes are performed at a high temperature of 500° C. or above, and produce a thin film having a very rough surface. According to the method of manufacturing a ferroelectric layer 50 using deposition and annealing at a temperature of 500° C. or below, the ferroelectric layer 50 is formed through a reaction and crystallization process from a solid state source material. Thus, the ferroelectric layer 50 having a minute and predetermined dominant orientation direction, and a high crystallinity can be obtained. Also, since the stoichiometric composition of the ferroelectric layer 50 can be readily controlled, a ferroelectric layer 50 having high ferroelectric characteristic can be obtained, thereby increasing recording density. Also, the ferroelectric layer 50 having a surface roughness of approximately 1 nm or less, that is, a very smooth surface, and a thickness of 20 nm or less can be manufactured.

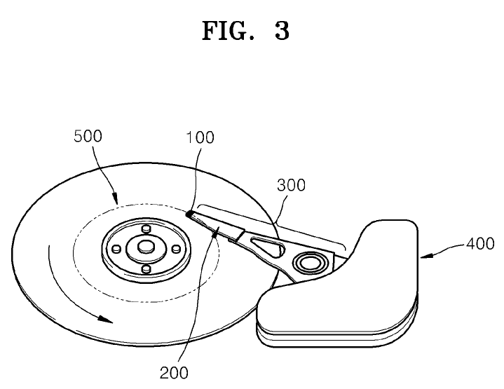

As an example, a ferroelectric recording medium 500 is manufactured as a rotatable disc type, and thus, may be applied to an electric field recording/reproducing apparatus that employs a driving mechanism of a hard disc drive. FIG. 3 is a perspective view of an electric field recording and reproducing apparatus having a driving mechanism of a hard disc drive. An electric field recording/reproducing head 100 is mounted on a suspension arm 200 provided on an end portion of a swing arm 300. The swing arm 300 is rotated by a voice coil motor 400. When the ferroelectric recording medium 500 is rotated, the electric field recording/reproducing head 100 rises from a surface of the ferroelectric recording medium 500 due to an air bearing effect. The electric field recording and reproducing apparatus of FIG. 3 has a driving system identical to that of a conventional hard drive disc (HDD), and a magnetic recording medium in the conventional HDD is replaced by the ferroelectric recording medium 500, and thus, a magnetic recording and reproducing head is replaced by the electric field recording/reproducing head 100. If a driving mechanism of a HDD is employed, generally, the electric field recording and reproducing head 100 performs a recording/reproducing operation of information in a state in which the electric field recording/reproducing head 100 is raised from the surface of the ferroelectric recording medium 500 due to the air bearing effect. If the surface roughness of the ferroelectric layer 50 is large, an air bearing surface of the electric field recording/reproducing head 100 collides with the ferroelectric layer 50 in a recording/reproducing operation, and thus, the air bearing surface of the electric field recording/reproducing head 100 and the surface of the ferroelectric layer 50 may be damaged. The ferroelectric layer 50 manufactured according to the method described above has a very smooth surface, that is, has a surface roughness of approximately 1 nm or less, and thus, collision between the air bearing surface of the electric field recording/reproducing head 100 and the ferroelectric layer 50 may be prevented. And, since the ferroelectric layer 50 manufactured according to the method described above has a very smooth surface, even though there is no protective layer and/or no lubricant such as diamond like carbon (DLC) for protecting the surface of the ferroelectric layer 50, the electric field recording/reproducing head 100 can be raised from the surface of the ferroelectric layer 50 due to the air bearing effect.

The method of manufacturing a ferroelectric recording medium according the exemplary embodiment will be described below. A glass substrate may be employed as the substrate 10. The glass substrate is inexpensive, and thus, if a ferroelectric recording medium is manufactured using the glass substrate, price competitiveness may be ensured.

Formation of an adhesive layer: After placing a Zr-target in a sputtering chamber, the adhesion layer 21 is formed to a thickness of approximately 8 nm on the substrate 10 by depositing Zr using a sputtering process. The sputtering process may be performed under predetermined conditions of, for example, a room temperature, an Ar gas atmosphere with 4 mTorr, and an RF power of 50 W.

Formation of an electrode layer: A Pt target is placed in the sputtering chamber. For example, the electrode layer 20 is formed to a thickness of approximately 25 nm by depositing Pt on the adhesion layer 21 using a sputtering process under predetermined conditions of, for example, an Ar atmosphere of 4 mTorr and an RF power of 50 W.

Formation of a deformation prevention layer: The deformation prevention layer 23 is formed on the substrate 10 by sequentially depositing Zr to a thickness of approximately 20 nm and Pt to a thickness of approximately 150 nm using a sputtering process. The sputtering process may be performed under predetermined conditions of, for example, a room temperature, an Ar gas atmosphere with 4 mTorr, and an RF power of 50 W.

Annealing: An Ar—O₂ mixture gas atmosphere which contains 5% oxygen is formed in an annealing chamber. The annealing chamber may be set at a pressure of 40 mTorr. The annealing chamber is preheated to approximately 300° C. prior to placing the substrate 10 in the annealing chamber. After placing the substrate 10 in the annealing chamber, the annealing chamber is maintained at a temperature of approximately 300° C. for approximately 2 minutes. The temperature of the annealing chamber is slowly increased to approximately 400° C. in order to prevent the substrate 10 from being applied by thermal stress that causes bending of the substrate 10. After maintaining the annealing chamber at the temperature of approximately 400° C. for approximately 2 minutes, the substrate 10 is taken out from the annealing chamber. In this process, oxygen is diffused into the adhesion layer 21 through the Pt-electrode layer 20 and oxidizes Zr into ZrO₂.

Cooling: The resultant product is cooled for approximately 30 minutes in a vacuum state.

Formation of an intermediate layer: Zr is deposited to a thickness of 2.6 nm on the electrode layer 20 using a sputtering process. The sputtering process may be performed under predetermined conditions of, for example, a room temperature, an Ar gas atmosphere with 4 mTorr, and an RF power of 50 W. Afterwards, an Ar—O₂ mixture gas atmosphere which contains 5% oxygen is formed in an annealing chamber. The annealing chamber may be set at a pressure of 40 mTorr. The annealing chamber may be preheated to a temperature of approximately 300° C. prior to placing the substrate 10 in the annealing chamber. The annealing chamber is maintained at the temperature of approximately 300° C. for approximately 2 minutes. The temperature of the annealing chamber is slowly increased to approximately 400° C. in order to prevent the substrate 10 from being applied by thermal stress that causes bending of the substrate 10. After maintaining the annealing chamber at the temperature of approximately 400° C. for approximately 1 minute, the substrate 10 is taken out of the annealing chamber. As a result of annealing, Zr is oxidized into ZrO₂ by oxygen on the Ar—O₂ mixture gas. ZrO₂ may be directly deposited on the electrode layer 20 from a ZrO₂ target, or ZrO₂ may be deposited on the electrode layer 20 by using a reactive sputtering using a Zr target. In this case, the annealing process may also be performed with respect to the resultant product.

Cooling: The resultant product is cooled for approximately 30 minutes in a vacuum state.

Formation of a ferroelectric layer: A PbO-material layer and a TiO₂-material layer are used as the source material layer 40 for forming a PbTiO₃-ferroelectric layer. In consideration of the stoichiometric composition of the PbTiO₃-ferroelectric layer, the thickness of the PbO-material layer must be 1.26 times of that of the TiO₂-material layer. However, the PbTiO₃-ferroelectric layer is a material that allows a large deviation from the stoichiometric composition, and thus, the composition ratio of the PbO-material layer may be controlled slightly over or under the stoichiometric composition. Four layers of the PbO-material layer having a thickness of 1.8 nm and the TiO₂-material layer having a thickness of 1.5 nm are deposited using a sputtering process at room temperature and a pressure of 10 mTorr under an Ar—O₂ mixture gas which contains 5% oxygen. In the present exemplary embodiment, the PbO-material layer is a starting layer; however, the TiO₂-material layer may be employed as the starting layer. A PbO-material layer as the capping layer 43 is deposited to a thickness of 1 nm on the source material layer 40 in order to prevent loss of Pb having volatility. Of course, PbTiO₃ may be directly deposited on the intermediate layer 30, and also, in this case, the PbO-material layer as the capping layer 43 may be deposited to a thickness of 1 nm on the PbTiO₃ layer. When the deposition of the source material 40 is completed, an annealing process for forming a ferroelectric layer is performed. An Ar—O₂ mixture gas atmosphere which contains 5% oxygen is formed in an annealing chamber. The pressure of the annealing chamber is controlled at 40 mTorr. Prior to placing the substrate 10 in the annealing chamber, the annealing chamber is preheated to a temperature of approximately 300° C. After placing the substrate 10 in the annealing chamber, the annealing chamber is maintained at the temperature of 300° C. for 2 minutes. The temperature of the annealing chamber is slowly increased to approximately 480° C. in order to prevent the substrate 10 from being subjected to thermal stress that causes bending of the substrate 10. After maintaining the annealing chamber at the temperature of approximately 480° C. for approximately 2 minutes, the temperature of the annealing chamber is reduced to 430° C. and is maintained for 1 minute at this temperature, and then, is reduced to 400° C. and is maintained for 1 minute at this temperature. The annealing chamber is cooled at a pressure of 40 mTorr under an Ar—O₂ mixture gas atmosphere which contains 5% oxygen. Afterwards, the substrate 10 is taken out from the annealing chamber. Thus, a PbTiO₃-ferroelectric layer having a thickness of 14 nm is formed on the intermediate layer 30.

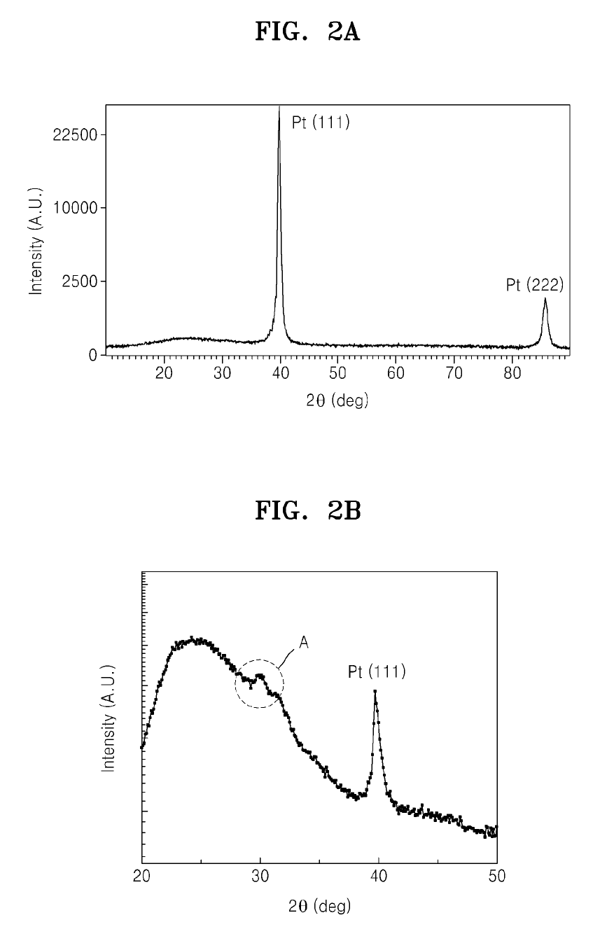

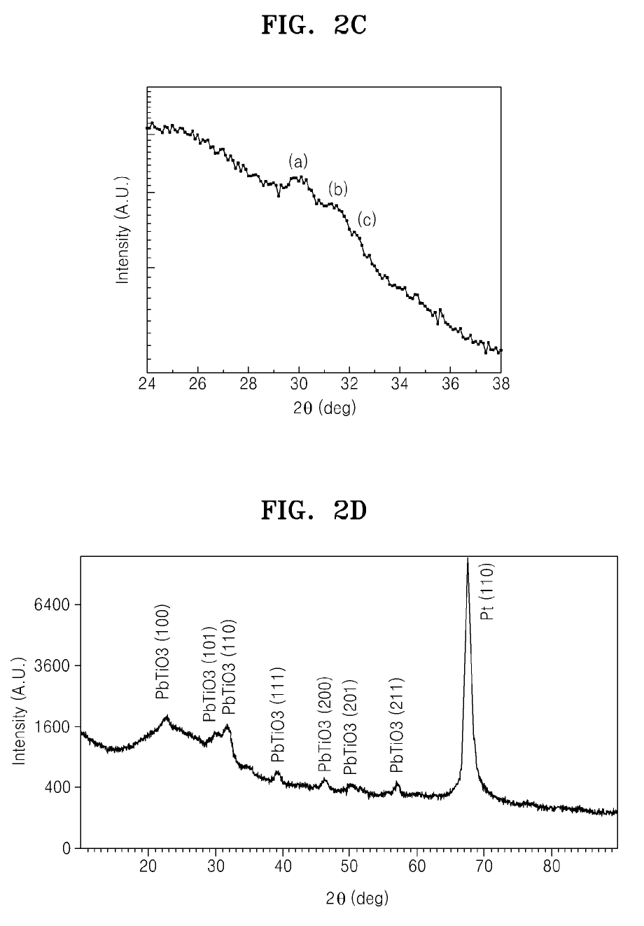

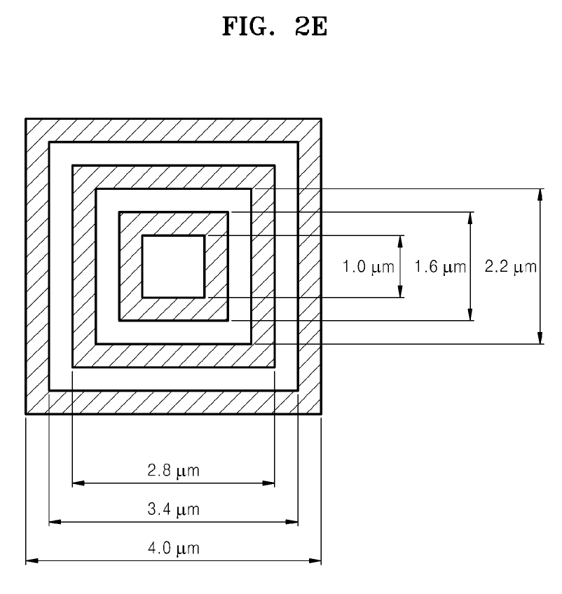

The ferroelectric recording medium manufactured according to the exemplary embodiment of the present invention described above is referred to as sample 1. FIG. 2A is a graph showing X-ray scan data with respect to sample 1. In FIG. 2A, a peak of the PbTiO₃-ferroelectric layer is not seen because the PbTiO₃-ferroelectric layer is too thin to generate a sufficient signal. In FIG. 2A, it is seen that a Pt-electrode layer is almost completely oriented in a (111) direction. FIG. 2B is a graph showing synchrotron scan data with respect to sample 1, and FIG. 2C is a magnified portion of A of FIG. 2B. The data of FIGS. 2B and 2C are obtained in an 8 degree offset state in order to prevent resonance of the Pt-electrode layer. Referring to FIG. 2C, (a) indicates a ZrO₂-intermediate layer having a tetragonal structure oriented in the (111) direction, (b) indicates a PbTiO₃-ferroelectric layer oriented in a (101) direction and (c) indicates a PbTiO₃-ferroelectric layer oriented in a (110) direction. FIG. 2D is a graph showing X-ray scan data of a thin film of sample 1. The peak of the PbTiO₃-ferroelectric layer can be clearly seen in FIG. 2D. Thus, the formation of the PbTiO₃-ferroelectric layer having a dominant orientation direction of (110) is confirmed since the (110) direction and the (101) direction belong to the same family. FIG. 2E is a schematic drawing for explaining a method of testing a ferroelectric characteristic of sample 1. +5 V and −5 V are sequentially applied to rectangular regions having side lengths of 4 μm, 3.4 μm, 2.8 μm, 2.2 μm, 1.6 μm, and 1.0 μm, respectively, on a surface of the ferroelectric of sample 1. Afterwards, polarization directions were investigated using a piezoelectric force microscope (PFM). It is observed that sample 1 was clearly switched due to the application of +5 V. The surface roughness of the sample 1 was measured using an atomic force microscope (ATM), and the result showed that a smooth surface having a root mean square (RMS) value of approximately 0.38 and a peak-to-peak value of approximately 4.9 nm was obtained.

Sample 2 was formed using the same process for forming sample 1 except that a ZrO₂-intermediate layer was not used in sample 2. The surface roughness of sample 2 was measured, and the result showed that sample 2 had a very rough surface having an RMS value of approximately 1 nm and a peak-to-peak value of approximately 56 nm. Also, the ferroelectric characteristic of sample 2 was investigated by applying voltages of ±5V, and showed an insufficient switching characteristic, that is, an insufficient ferroelectric characteristic.

Sample 3 was formed using the same process for forming sample 1 except that 2×(a PbO layer with a thickness of 3.6 nm and a TiO2 layer with a thickness of 3.0 nm) were used as a source material layer. The surface roughness of sample 3 was measured, and the result showed that sample 3 had a very smooth surface having an RMS value of approximately 0.47 nm and a peak-to-peak value of approximately 4.9 nm. Also, the ferroelectric characteristic of sample 3 was investigated by applying voltages of ±5V, and the result showed that sample 3 had a very clean switching characteristic.

Sample 4 was formed using the same process for forming sample 1 except that a ZrO₂-intermediate layer having a thickness of 1.6 nm was used. The ferroelectric characteristic of sample 4 was investigated by applying voltages of ±5 V, and the result showed that sample 4 had a very clean switching characteristic.

Sample 5 was formed using the same process for forming sample 3 except that a ZrO₂-intermediate layer having a thickness of 1.0 nm was used as a source material layer. The surface roughness of sample 5 was measured, and the result showed that sample 5 had a very smooth surface having an RMS value of approximately 0.54 nm and a peak-to-peak value of approximately 5.9 nm. Also, the ferroelectric characteristic of sample 2 was investigated by applying voltages of ±5 V, and the result showed that sample 5 had a very clean switching characteristic.

Sample 6 was formed using the same process for forming sample 1 except that 2×(a TiO2 layer with a thickness of 3.0 nm and a PbO layer with a thickness of 4.1 nm) were used as a source material layer and the TiO₂ layer was used as a starting layer instead of the PbO layer. The surface roughness of sample 6 was measured, and the result showed that sample 6 had a very smooth surface having an RMS value of approximately 0.35 nm and a peak-to-peak value of approximately 2.8 nm. Also, the ferroelectric characteristic of the sample 6 was investigated by applying voltages of ±5 V, and the result showed that the sample 6 had a very clean switching characteristic.

In the exemplary embodiment of the present invention, a method of manufacturing a PbTiO₃-ferroelectric layer using a ZrO₂-intermediate layer has been described. However, the method described above can also be applied to manufacture the PbTiO₃-ferroelectric layer using an intermediate layer of, for example, TiO₂, MgO₂, SrTiO₃, Al₂O₃, HfO₂, Nb oxide, SiO₂, or ZnO₂, and also, can be applied to manufacture other ferroelectric layers of, for example, Pb(Zr, Ti)O₃, LiNbO₂, LiTaO₃, BiFeO₃, or PVDF.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of manufacturing a ferroelectric recording medium, the method comprising:
forming an electrode layer of a conductive material layer on a substrate;
forming an intermediate layer of a dielectric material layer on the electrode layer;
forming a source material layer on the intermediate layer; and
forming a ferroelectric layer from the source material layer by performing an annealing process.

2. The method of claim 1, further comprising forming a capping layer on the source material layer to prevent volatilization of the source material layer.

3. The method of claim 1, wherein the ferroelectric layer is formed of one material selected from a group consisting of PbTiO₃, Pb(Zr, Ti)O₃, LiNbO₂, LiTaO₃, BiFeO₃, and PVDF.

4. The method of claim 1, wherein the intermediate layer is formed of one material selected from a group consisting of ZrO₂, TiO₂, MgO₂, SrTiO₃, Al₂O₃, HfO₂, Nb oxide, SiO₂, and ZnO₂.

5. The method of claim 1, wherein the source material layer and the ferroelectric layer are made of the same material.

6. The method of claim 1, wherein the source material layer comprises a plurality of material layers that form the ferroelectric layer by a reaction occurring between the material layers.

7. The method of claim 6, wherein the material layers are alternatively stacked at least two times.

8. The method of claim 1, wherein the annealing process for forming the ferroelectric layer is performed at a temperature of 500° C. or below.

9. The method of claim 1, wherein the forming of the electrode layer comprises:
forming the conductive material layer on the substrate by depositing a conductive material; and
annealing the substrate on which the conductive material layer is formed at a temperature of 500° C. or below.

10. The method of claim 9, wherein the forming of the electrode layer further comprises, prior to annealing the substrate on which the conductive material layer is formed, forming a deformation prevention layer on a surface of the substrate opposite to the surface on which the conductive material layer is formed to prevent the substrate from being deformed during the annealing process.

11. The method of claim 1, wherein the forming of the intermediate layer comprises:
depositing a dielectric seed material on the substrate; and
forming the dielectric material layer by oxidizing the dielectric seed material by performing an annealing process in a gas atmosphere that contains oxygen.

12. A method of manufacturing a ferroelectric recording medium, the method comprising:
forming an electrode layer on a substrate by depositing a conductive material layer on the substrate and annealing the conductive material layer;
forming an intermediate layer on the electrode layer, wherein the intermediate layer is formed of one material selected from a group consisting of ZrO₂, TiO₂, MgO₂, SrTiO₃, Al₂O₃, HfO₂, Nb oxide, SiO₂, and ZnO₂;
depositing at least one source material layer on the intermediate layer to form a ferroelectric layer formed of a material selected from a group consisting of PbTiO₃, Pb(Zr, Ti)O₃, LNbO₂, LiTaO₃, BiFeO₃, and PVDF; and
forming the ferroelectric layer from the source material layer by performing an annealing process at a temperature of 500° C. or below in an Ar—O₂ mixture gas atmosphere which contains 5% oxygen.

13. The method of claim 12, further comprising forming a capping layer on the source material layer.

14. The method of claim 12, wherein the source material layer is and the ferroelectric layer are made of the same material.

15. The method of claim 12, wherein the source material layer comprises a plurality of material layers that form the ferroelectric layer by a reaction occurring between the material layers, and the material layers are alternatively stacked at least two times.

16. A ferroelectric recording medium comprising:
a substrate;
an electrode layer disposed on the substrate;
a ferroelectric layer; and
an intermediate layer interposed between the electrode layer and the ferroelectric layer, wherein the intermediate layer induces the crystal orientation direction of the ferroelectric layer in a predetermined dominant orientation direction is.

17. The ferroelectric recording medium of claim 16, further comprising a deformation prevention layer disposed on a surface of the substrate opposite to a surface on which the electrode layer is disposed in order to prevent the substrate from being deformed.

18. The ferroelectric recording medium of claim 16, further comprising:
an adhesive layer interposed between the substrate and the electrode layer; and
a deformation prevention layer disposed on a surface of the substrate opposite to the surface on which the electrode layer is disposed in order to prevent the substrate from being deformed,
wherein the deformation prevention layer has a multi-layer structure formed of the same material used to form the electrode layer and the adhesive layer.

19. The ferroelectric recording medium of claim 16, wherein the ferroelectric layer is formed of a material selected from a group consisting of PbTiO₃, Pb(Zr, Ti)O₃, LiNbO₂, LiTaO₃, BiFeO₃, and PVDF.

20. The ferroelectric recording medium of claim 19, wherein the intermediate layer is formed of a material selected from a group consisting of ZrO₂, TiO₂, MgO₂, SrTiO₃, Al₂O₃, HfO₂, Nb oxide, SiO₂, and ZnO₂.
